(19) United States
(12) Patent Application Publication
(10) Pub. No.: US 2024/0201276 A1
(43) Pub. Date: Jun. 20, 2024

(54) METHOD OF DIAGNOSING REDUNDANT POWER SUPPLY AND STORAGE MEDIUM

(71) Applicant: TOYOTA JIDOSHA KABUSHIKI KAISHA, Toyota-shi (JP)

(72) Inventor: Naoki TSUDA, Toyota-shi (JP)

(73) Assignee: TOYOTA JIDOSHA KABUSHIKI KAISHA, Toyota-shi (JP)

(21) Appl. No.: 18/480,025

(22) Filed: Oct. 3, 2023

(30) Foreign Application Priority Data
Dec. 15, 2022 (JP) 2022-200218

(51) Int. Cl. G01R 31/392; B60R 16/033; G01R 31/367; G01R 31/389; G07C 5/08; H01M 10/44; H01M 10/48

(52) U.S. Cl. CPC G01R 31/392; B60R 16/033; G01R 31/367; G01R 31/389; G07C 5/0808; H01M 10/44; H01M 10/48; H01M 2220/20

(57) ABSTRACT

A method for diagnosing a redundant power supply executed by a computer of an apparatus for diagnosing a state of a battery mounted on a vehicle, the method comprising the steps of: performing a discharge process for discharging a battery according to a predetermined discharge pattern; performing a deterioration diagnosis of the battery when the first information obtained by the discharge process satisfies a predetermined condition; estimating an internal resistance value of the battery based on the second information acquired at the time of performing the latest diagnosis satisfying the predetermined condition if the first information does not satisfy the predetermined condition; and determining a state of the battery using the estimated internal resistance value of the battery.

### CROSS-REFERENCE TO RELATED APPLICATION

This application claims priority to Japanese Patent Application No. 2022-200218 filed on Dec. 15, 2022, incorporated herein by reference in its entirety.

### BACKGROUND

### 1. Technical Field

The present disclosure relates to a method of diagnosing a backup battery mounted as a redundant power supply in a vehicle, and the like.

### 2. Description of Related Art

Japanese Unexamined Patent Application Publication No. 2022-064649 (JP 2022-064649 A) discloses a battery diagnosis device that diagnoses a state of a sub-battery (backup battery) for backup of a main battery mounted in a vehicle during autonomous driving. The battery diagnosis device described in JP 2022-064649 A repeatedly performs a retry discharge process of up to further two times at maximum, when the deterioration diagnosis of the backup battery cannot be performed by a first diagnostic discharge process.

### SUMMARY

A battery diagnosis device described in JP 2022-064649 A performs a plurality of retry discharge processes. However, when the power consumption by an in-vehicle device occurs at a timing when the retry discharge process is performed, a normal discharge process cannot be executed, and the retry discharge process may fail.

As described above, when the deterioration diagnosis of the backup battery by the discharge process cannot be performed, it is determined that the backup battery cannot be used in order to prioritize the safety of a vehicle even when there is no problem in the backup battery.

The present disclosure has been made in view of the above issue, and an object of the present disclosure is to provide a method of diagnosing a redundant power supply and the like capable of determining whether the battery can be used even when the deterioration diagnosis of the battery (backup battery or the like) by the discharge process cannot be performed.

In order to solve the above issue, an aspect of the disclosed technique is a method of diagnosing a redundant power supply executed by a computer of a device that diagnoses a state of a battery mounted in a vehicle, and the method includes:
a step of performing a discharge process for discharging by a predetermined discharge pattern from the battery;
a step of performing a deterioration diagnosis of the battery when first information obtained by the discharge process satisfies a predetermined condition;
a step of estimating an internal resistance value of the battery based on second information acquired at the time of the latest diagnosis satisfying the predetermined condition, when the first information does not satisfy the predetermined condition; and
a step of determining the state of the battery using the estimated internal resistance value of the battery.

With the method of diagnosing the redundant power supply according to the present disclosure, when the deterioration diagnosis of the battery by the discharge process cannot be performed, the state of the battery is grasped based on the current internal resistance value of the battery that can be estimated from the information at the time of the latest deterioration diagnosis of the battery by the discharge process. Thus, it is possible to determine whether the battery can be used.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a functional block diagram of a battery diagnosis device capable of executing a redundant power supply diagnosis method according to the present embodiment and a peripheral portion thereof;

FIG. 2 shows the current path emitted from the second battery in the diagnostic discharge process;

FIG. 3 is a diagram illustrating an example of a change in the physical quantity of the second battery in the diagnostic discharge process;

FIG. 4A is a flow chart of a degradation diagnosis process of a second battery executed by a battery diagnosis device; and

FIG. 4B is a flow chart of a degradation diagnosis process of a second battery executed by a battery diagnosis device.

### DETAILED DESCRIPTION OF EMBODIMENTS

The battery diagnosis device according to the present disclosure estimates the internal resistance value of the current battery from the latest information among the past information in which the deterioration diagnosis of the backup battery by the discharge process can be performed when the deterioration diagnosis of the backup battery by the discharge process cannot be performed with respect to the backup battery during the automatic operation. Then, based on the estimated internal resistance value of the backup battery, the battery diagnosis device determines whether or not the backup battery can be used for automatic operation.

Hereinafter, an embodiment of the present disclosure will be described in detail with reference to the drawings.

### Embodiment

### Configuration

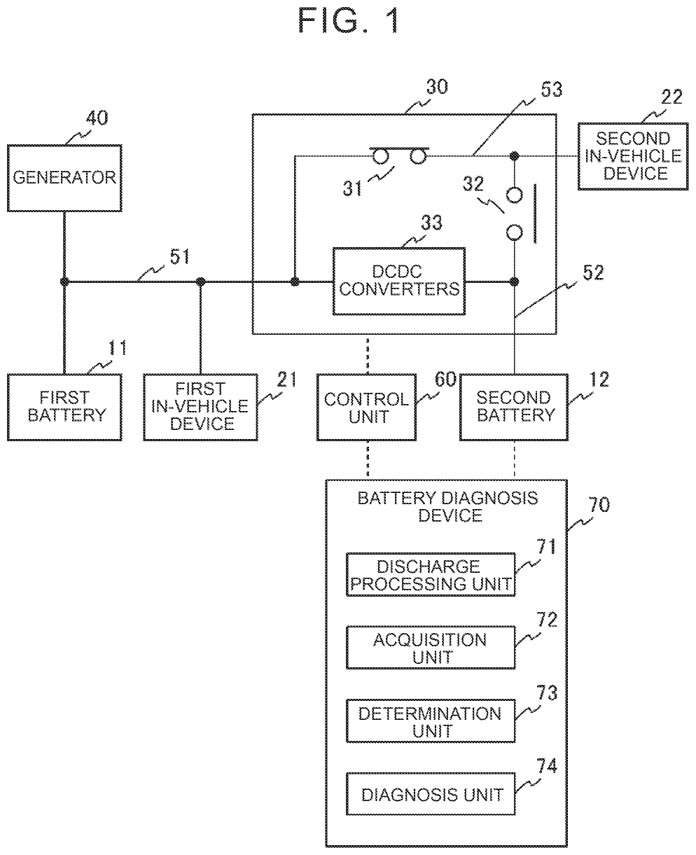

FIG. 1 is a functional block diagram of a battery diagnosis device 70 capable of executing a method for diagnosing a redundant power supply according to an embodiment of the present disclosure and a peripheral portion thereof. The functional block illustrated in FIG. 1 includes a first battery 11, a second battery 12, a first in-vehicle device 21, a second in-vehicle device 22, a connection switching unit 30, a generator 40, a control unit 60, and a battery diagnosis device 70.

The first battery 11, the first in-vehicle device 21, the connection switching unit 30, and the generator 40 are connected to each other by a first power line 51. The second battery 12 and the connection switching unit 30 are connected by a second power line 52. The second in-vehicle device 22 and the connection switching unit 30 are connected by a third power line 53. The second battery 12, the connection switching unit 30, the control unit 60, and the battery diagnosis device 70 are connected by a signal line (a dotted line in FIG. 1), and control signals, measurement values, and the like are transmitted and received.

A case where the battery diagnosis device 70 according to the present embodiment is mounted on a vehicle that is capable of switching between manual driving and automatic driving and includes a power supply system that requires a redundant power supply configuration will be described as an example.

The generator 40 is a device capable of outputting predetermined electric power, for example, an alternator or a DCDC converter. The electric power output from the generator 40 is supplied to the first battery 11, the first in-vehicle device 21, and the like.

The first battery 11 is a secondary battery configured to be chargeable and dischargeable, such as a lead-acid battery or a lithium-ion battery. The first battery 11 stores electric power output from the generator 40. Further, the first battery 11 discharges the electric power stored by itself to the first in-vehicle device 21 and the connection switching unit 30. The first battery 11 is provided as a main battery used exclusively for traveling of the vehicle.

The second battery 12 is a secondary battery configured to be chargeable and dischargeable, such as a lead-acid battery or a lithium-ion battery. The second battery 12 stores the electric power output from the generator 40 and the electric power of the first battery 11 by itself via the connection switching unit 30. Further, the second battery 12 discharges (supplies) the electric power stored by itself to the second in-vehicle device 22 or the like via the connection switching unit 30. The second battery 12 is provided as a redundant power supply (backup battery) capable of performing a backup process of maintaining power supply to the second in-vehicle device 22 that is responsible for the automatic operation in place of the first battery 11 even when the first battery 11 fails during the automatic operation.

The first in-vehicle device 21 is a load that consumes electric power mounted on the vehicle. The first in-vehicle device 21 is configured to operate with electric power output from the generator 40 and/or electric power stored in the first battery 11.

The second in-vehicle device 22 is a load that consumes electric power mounted on the vehicle, and may be a device that is required to supply electric power more stably than the first in-vehicle device 21 during automatic driving of the vehicle. More specifically, the second in-vehicle device 22 is an important device related to safe driving of a vehicle that requires power supply from the second battery 12 for a predetermined period and with a predetermined current even when the power supply from the first battery 11 fails. For example, the second in-vehicle device 22 may be a device that performs an important function for safely evacuating the vehicle in the event of an emergency in automatic driving. The second in-vehicle device 22 is configured to operate with electric power output from the generator 40 and/or electric power stored in the first battery 11 during manual operation, and to operate with electric power output from the generator 40 voltage-controlled by DCDC converters 33 and/or electric power stored in the first battery 11 and electric power stored in the second battery 12 during automated operation.

The connection-switching unit 30 includes a first switch 31, a second switch 32, and a DCDC converter 33 in a configuration. The first switch 31 is openably and closably disposed between the first power line 51 and the third power line 53. The second switch 32 is openably and closably disposed between the second power line 52 and the third power line 53. For the first switch 31 and the second switch 32, for example, a semiconductor relay, a mechanical relay, or the like can be used. DCDC converter 33 is a voltage converter that is disposed between the first power line 51 and the second power line 52 and converts the voltage of the inputted power into a predetermined voltage and outputs the converted voltage. DCDC converter 33 can be, for example, a step-up/step-down type DCDC converter having a step-down function of stepping down the voltage on the primary side and outputting the voltage on the secondary side, and a step-up function of stepping up the voltage on the secondary side and outputting the voltage on the primary side.

The control unit 60 is configured by an automated driving ECU (Electronic Control Unit) including, for example, a microcomputer. The control unit 60 controls the opening and closing states of the first switch 31 and the second switch 32 of the connection-switching unit 30 and the voltage-indicating values of DCDC converters 33 on the basis of vehicle information (an ON/OFF state of an ignition, a state of manual driving/autonomous driving, and the like) acquired from an in-vehicle device (not shown).

Specifically, when the vehicle is in the manual driving state, the control unit 60 closes the first switch 31 to connect the first power line 51 and the third power line 53, and opens the second switch 32 to disconnect the second power line 52 and the third power line 53. As a result, the electric power output from the generator 40 and/or the electric power stored in the first battery 11 is directly supplied to the second in-vehicle device 22. On the other hand, when the vehicle is in the autonomous driving state, the control unit 60 opens the first switch 31 to disconnect the first power line 51 and the third power line 53, and closes the second switch 32 to connect the second power line 52 and the third power line 53. Thus, the electric power outputted from the generator 40 and/or the electric power stored in the first battery 11 are indirectly supplied to the second in-vehicle device 22 via DCDC converters 33.

The battery diagnosis device 70 is a device for determining whether or not the second battery 12 can be used during automatic operation, and for diagnosing a state of the second battery 12, which is a backup battery of the first battery 11. The diagnosis of the state of the second battery 12 is, more specifically, a diagnosis related to deterioration of the second battery 12. The battery diagnosis device 70 includes a discharge processing unit 71, an acquisition unit 72, a determination unit 73, and a diagnosis unit 74.

When the timing at which the deterioration diagnosis of the second battery 12 is performed comes, the discharge processing unit 71 performs a diagnostic discharge process of discharging from the second battery 12 according to a predetermined discharge pattern. Specifically, the discharge processing unit 71 performs a diagnostic discharge process of discharging from the second battery 12 toward the first in-vehicle device 21 and the second in-vehicle device 22 for the first time period.

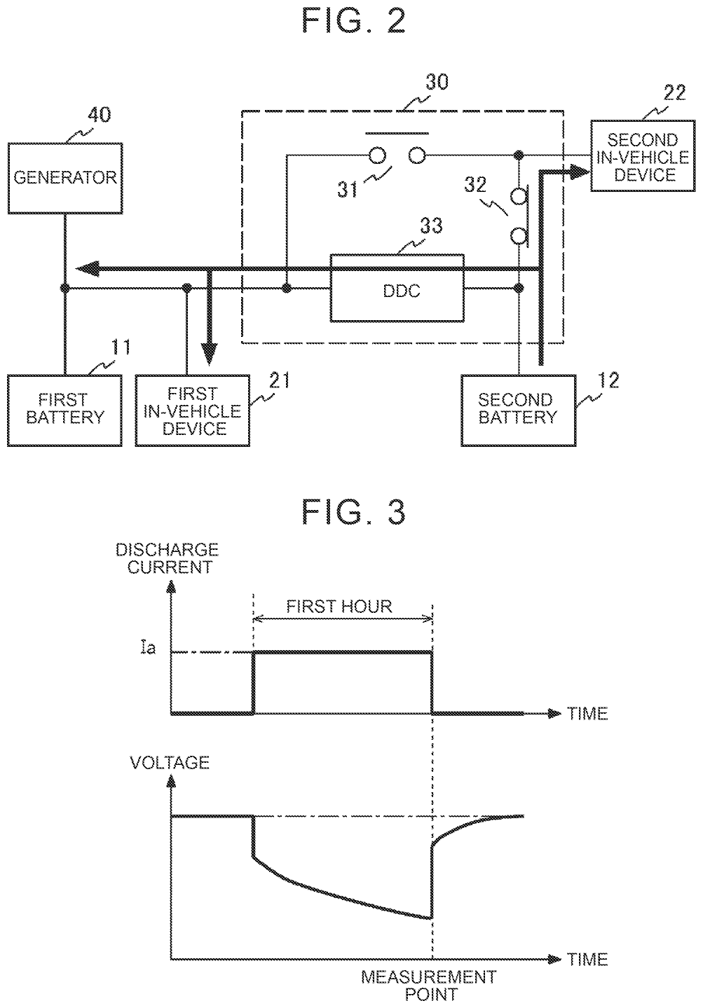

FIG. 2 shows a current emission path (arrow in FIG. 2) in the diagnostic discharge process performed by the discharge processing unit 71. A current is emitted from the second battery 12 to the first in-vehicle device 21 through DCDC converters (DDC) 33, and a current is emitted from the second battery 12 to the second in-vehicle device 22 through the second switch 32.

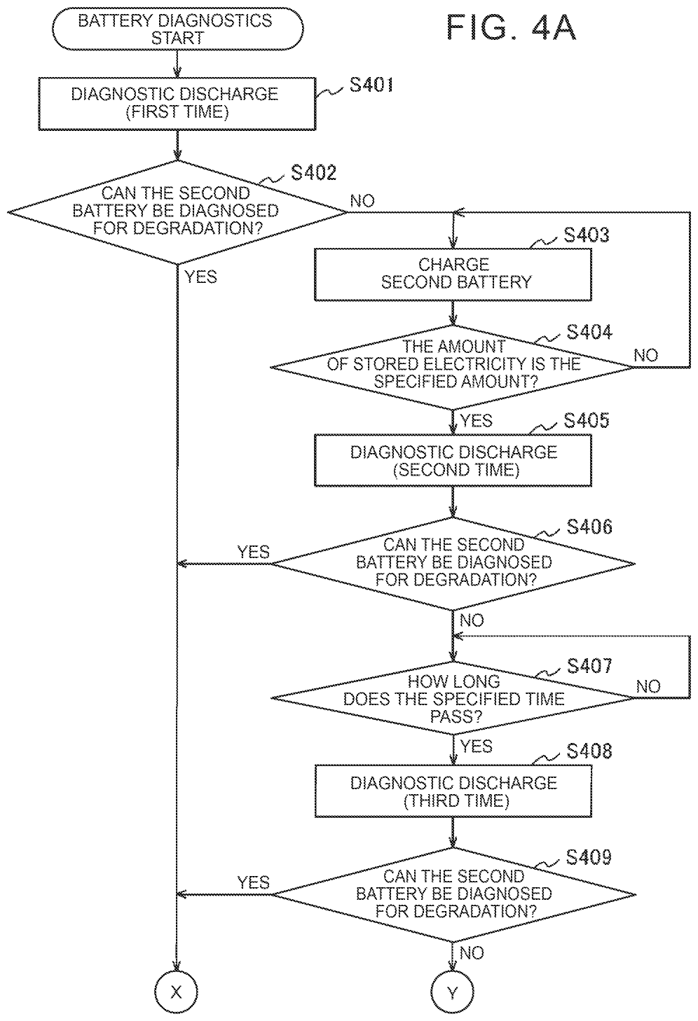

FIG. 3 shows changes in the outflow current and the output voltage of the second battery 12 during the diagnostic discharge. As shown in FIG. 3, during the diagnostic discharging, DCDC converters (DDC) 33 are controlled such that a constant value Ia current continues to flow out of the second battery 12 for a first period of time. The constant value Ia is appropriately set based on a current (actual backup current) that must be continuously supplied from the second battery 12 to the second in-vehicle device 22 for the first time (for example, 15 seconds) during the backup process. This diagnostic discharging process can be repeated once or twice in accordance with the determination result of the determination unit 73, which will be described later.

The acquisition unit 72 acquires the physical quantity indicating the state of the second battery 12 while the discharge processing unit 71 performs the diagnostic discharge processing. The physical quantity indicating the state of the second battery 12 can be acquired from a detection device such as a sensor (not shown) mounted on the vehicle. Examples of the physical quantity indicating the state of the second battery 12 include voltage, current, and temperature. In the present embodiment, the acquisition unit 72 acquires the current (outflow current) and the output voltage emitted from the second battery 12 as the physical quantity.

The acquisition unit 72 derives the internal resistance value of the second battery 12 from the acquired voltage and current. Further, the acquisition unit 72 acquires the integrated time at the time when the deterioration diagnosis of the second battery 12 is performed. The accumulated time is a time (number of days) elapsed from the time when the use of the second battery 12 is started (for example, when a new battery is replaced), and can be acquired from a clocking device such as a clock or a calendar mounted on the vehicle. The internal resistance value and the integrated time are stored in a memory or the like (not shown).

The determination unit 73 determines whether or not diagnosis (deterioration diagnosis) regarding deterioration of the second battery 12 is possible based on the physical quantity indicating the state of the second battery 12 acquired by the acquisition unit 72. For example, the deterioration diagnosis of the second battery 12 is performed depending on whether or not the electric power that can be supplied by the second battery 12 derived from the outflow current and the output voltage of the second battery 12 obtained by the diagnostic discharge process satisfies the electric power required as the backup power source of the first battery 11. Therefore, the accuracy of the outflow current and the output voltage of the second battery 12 acquired by the acquisition unit 72 is required. The determination unit 73 determines whether or not the deterioration diagnosis of the second battery 12 is possible based on whether or not the accuracy of the outflow current and the output voltage of the second battery 12 acquired by the acquisition unit 72 is high. The accuracy of the outflow current and the output voltage of the second battery 12 will be described later.

When the determination unit 73 determines that the deterioration diagnosis of the second battery 12 is possible, the diagnosis unit 74 performs the deterioration diagnosis of the second battery 12 based on the physical quantity (the outflow current and the output voltage) indicating the state of the second battery 12 acquired by the acquisition unit 72. In this degradation diagnosis, it is diagnosed whether or not the second battery 12 is in a state of being able to be backed up when the first battery 11 fails.

In addition, when the determination unit 73 determines that the deterioration diagnosis of the second battery 12 is impossible, the diagnosis unit 74 determines whether the second battery 12 can be used as a backup battery during the automatic operation based on the internal resistance value and the integrated time of the second battery 12 stored in the memory or the like by the acquisition unit 72 and the elapsed time (described later).

Note that some or all of the above-described battery diagnosis device 70 may typically be configured as an electronic control unit (ECU) including a processor such as a microcomputer, memories, input/output interfaces, and the like. The electronic control device can realize some or all of the functions of the discharge processing unit 71, the acquisition unit 72, the determination unit 73, and the diagnosis unit 74 by the processor reading and executing the program stored in the memory.

### Control

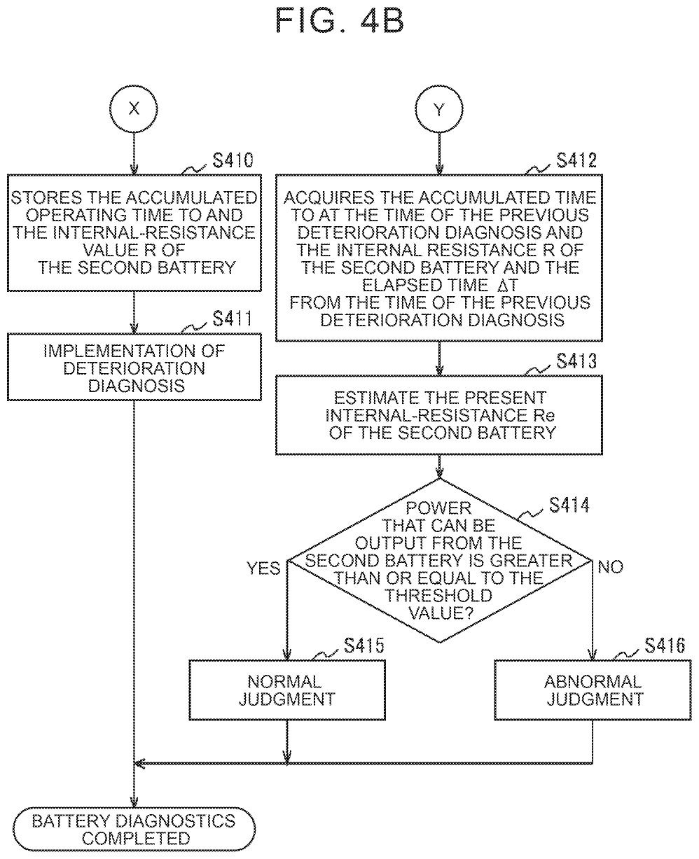

Next, the control executed by the battery diagnosis device 70 according to the present embodiment will be described with reference to FIGS. 4A and 4B. FIGS. 4A and 4B are flow charts for explaining the steps of the degradation diagnosis process of the second battery 12 performed by the respective components of the battery diagnosis device 70 during the manual operation. The process of FIG. 4A and the process of FIG. 4B are connected by the couplers X and Y.

The deterioration diagnosis process of the second battery 12 illustrated in FIGS. 4A and 4B is started when the power of the vehicle is turned on, and is repeatedly executed at a predetermined timing until the power is turned off while the vehicle is traveling by manual driving. Note that the battery diagnosis process is terminated at a time point when the vehicle is switched from traveling by manual driving to traveling by automatic driving.

### S401

The discharge processing unit 71 performs the first diagnostic discharge processing. As described above, the diagnostic discharge is performed by a discharge pattern in which a current having a constant value Ia flows from the second battery 12 toward the first in-vehicle device 21 and the second in-vehicle device 22 (FIG. 2) during the first period (FIG. 3). While the diagnostic discharge is being performed, the physical quantity (first information) of the second battery 12 is appropriately acquired by the acquisition unit 72. When the first diagnostic discharge processing is performed by the discharge processing unit 71, the processing proceeds to S402.

### S402

The determination unit 73 determines whether or not the deterioration diagnosis of the second battery 12 is possible. This determination is made based on the physical quantity (first information) of the second battery 12 acquired by the acquisition unit 72, for example, based on whether or not the following predetermined conditions are satisfied.
(1) The average value of the outflow current of the second battery 12 in one hour which is the discharge period is not equal to or larger than the first threshold value
(2) The outflow current of the second battery 12 at the end of discharge (measurement point in FIG. 3) at which one hour has elapsed is not equal to or larger than the second threshold value

The condition (1) assumes a situation in which a current demand that cannot be absorbed by the control of DCDC converters 33 is generated in the second in-vehicle device 22. In such a situation, the current supplied from the second battery 12 to the second in-vehicle device 22 is disturbed during the diagnostic discharge, and the deterioration of the battery cannot be correctly diagnosed by the physical quantity of the second battery 12 acquired by the acquisition unit 72. Therefore, the condition (1) is determined. The first thresholds are appropriately set based on the constant value Ia current and the backup actual current flowing in the diagnostic discharging.

Condition (2) assumes a scene in which the outflow current of the second battery 12 greatly changes at the end of discharging after the first time has elapsed even when the condition (1) is satisfied. In such a situation, the power (=outflow current×output voltage) that can be output from the second battery 12 derived from the physical quantity of the second battery 12 acquired by the acquisition unit 72 fluctuates, and deterioration of the battery cannot be correctly diagnosed. Therefore, the condition (2) is determined. The second threshold value is appropriately set based on the supply power required for the second battery 12 as the backup power supply of the first battery 11.

If any one of the conditions (1) and (2) cannot be satisfied, that is, if the average value of the outflow current of the second battery 12 in the first time is equal to or greater than the first threshold value, or if the outflow current of the second battery 12 at the end of discharge after the lapse of the first time is equal to or greater than the second threshold value, the determination unit 73 determines that the deterioration diagnosis of the battery is not possible (impossible).

When the determination unit 73 determines that the degradation of the second battery 12 can be diagnosed (S402, Yes), the process proceeds to S410. On the other hand, when the determination unit 73 determines that the degradation of the second battery 12 cannot be diagnosed (S402, No), the process proceeds to S403.

### S403

The discharge processing unit 71 charges the second battery 12 in preparation for the second diagnostic discharge processing. This charge is performed by the discharge processing unit 71 instructing the control unit 60 to control DCDC converters 33. When the second battery 12 is charged by the discharge processing unit 71, the processing proceeds to S404.

### S404

The discharge processing unit 71 determines whether or not the storage amount of the second battery 12 has reached a predetermined storage amount (first storage amount). This determination is made in preparation for a case where the third diagnostic discharge process is subsequently performed after the second diagnostic discharge process. That is, the discharge processing unit 71 increases the amount of stored electricity in advance so that the amount of stored electricity of the second battery 12 does not excessively decrease even if the diagnostic discharge is performed twice continuously. Therefore, the predetermined amount of electric power storage is an amount of electric power storage that does not enter an overdischarge state even if the diagnostic discharge is performed twice in succession.

When the discharging processing unit 71 determines that the storage amount of the second battery 12 has reached the predetermined storage amount (S404, No), the charging is continuously performed, and when it is determined that the storage amount of the second battery 12 has reached the predetermined storage amount (S404, yes), the processing proceeds to S405.

### S405

The discharge processing unit 71 performs the second diagnostic discharge processing. The diagnostic discharge is as described above. In order to stabilize the outflow current of the second battery 12, the second diagnostic discharge process is preferably performed during a period in which a large current demand by the second in-vehicle device 22 that has occurred in the first diagnostic discharge process does not occur. While the second diagnostic discharge is being performed, the physical quantity of the second battery 12 is appropriately acquired by the acquisition unit 72. When the discharge processing unit 71 performs the second diagnostic discharge processing, the processing proceeds to S406.

### S406

The determination unit 73 determines whether or not the deterioration diagnosis of the second battery 12 is possible. This determination method is as described in the above S402.

When the determination unit 73 determines that the degradation of the second battery 12 can be diagnosed (S406, Yes), the process proceeds to S410. On the other hand, when the determination unit 73 determines that the degradation of the second battery 12 cannot be diagnosed (S406, No), the process proceeds to S407.

### S407

The discharge processing unit 71 determines whether or not a predetermined time (second time) has elapsed since the second diagnostic discharge processing ended. This determination is made in preparation for the execution of the third diagnostic discharge process. That is, since there is a possibility that polarization occurs in the second battery 12 immediately after discharge (CC discharge) at a constant current is performed by the second diagnostic discharge process, the above determination is performed in order to eliminate the effect of polarization. Therefore, the predetermined time is set to a sufficient time until the polarization of the second battery 12 is eliminated.

Until the discharging processing unit 71 determines that the predetermined time has elapsed (S407, No), the time counting is continuously performed, and when it is determined that the predetermined time has elapsed (S407, Yes), the processing proceeds to S408.

### S408

The discharge processing unit 71 performs the third diagnostic discharge processing. The diagnostic discharge is as described above. The reason why the third diagnostic discharge process is performed following the second diagnostic discharge process is that even if a large current demand is generated by the second in-vehicle device 22 in the second diagnostic discharge process, there is a high possibility that the third diagnostic discharge process will not occur. While the third diagnostic discharge is being performed, the physical quantity of the second battery 12 is appropriately acquired by the acquisition unit 72. When the discharge processing unit 71 performs the third diagnostic discharge processing, the processing proceeds to S409.

### S409

The determination unit 73 determines whether or not the deterioration diagnosis of the second battery 12 is possible. This determination method is as described in the above S402.

When the determination unit 73 determines that the degradation of the second battery 12 can be diagnosed (S409, Yes), the process proceeds to S410. On the other hand, when the determination unit 73 determines that the degradation of the second battery 12 cannot be diagnosed (S409, No), the process proceeds to S412.

### S410

The acquisition unit 72 acquires information (second information) including at least an internal resistance value R (measured value) of the second battery 12 at the time of performing the degradation diagnosis process and an integrated time T0 that is an elapsed time from the beginning of use of the second battery 12 to the present. Then, the acquisition unit 72 stores this information (second information) in a memory or the like. In general, it is known that the rate of increase of the internal resistance value of a battery is proportional to the square root of the elapsed time (days). Therefore, the internal resistance value R of the second battery 12 is calculated from the internal resistance value R0 of the second battery 12 at the beginning (when the battery is new) and the resistance value increasing rate (slope factor) a according to the following equation [1].

$$R = R 0 \times ( 1 + α \times \sqrt{} T 0 ) \qquad [ 1 ]$$

When the acquisition unit 72 stores the internal-resistance value R and the integrated-time T0 of the second battery 12, the process proceeds to S411.

### S411

The diagnosis unit 74 performs the deterioration diagnosis of the second battery 12. The deterioration diagnosis is performed based on whether or not the electric power that can be supplied from the second battery 12 can be backed up when the first battery 11 fails, based on the physical quantity of the second battery 12 acquired by the acquisition unit 72. More specifically, when it is determined that the deterioration diagnosis of the second battery 12 is possible in the first diagnostic discharge process, the physical quantity of the second battery 12 acquired by the acquisition unit 72 during the first diagnostic discharge is used for the diagnosis. When it is determined that the deterioration diagnosis of the second battery 12 is possible in the second diagnostic discharge process, the physical quantity of the second battery 12 acquired by the acquisition unit 72 during the second diagnostic discharge is used for the diagnosis. When it is determined that the deterioration diagnosis of the second battery 12 is possible in the third diagnostic discharge process, the physical quantity of the second battery 12 acquired by the acquisition unit 72 during the third diagnostic discharge is used for the diagnosis. When the diagnosis unit 74 diagnoses the deterioration state of the second battery 12, the present battery diagnosis process ends.

### S412

The diagnosis unit 74 acquires the internal resistance value R of the second battery 12 and the integrated time T0 at that time when the deterioration diagnosis of the second battery 12 is performed last time (most recently), and the elapsed time ΔT from the previous deterioration diagnosis of the second battery 12 to the current deterioration diagnosis of the second battery 12 from the memory or the like. When the diagnosis unit 74 acquires the internal-resistance value R, the integrated time T0, and the elapsed time ΔT of the second battery 12, the process proceeds to S413.

### S413

The diagnosis unit 74 estimates the present internal resistance value Re of the second battery 12 based on the internal resistance value R, the integrated time T0, and the elapsed time ΔT of the second battery 12. This estimation is performed as follows.

First, based on the above equation [1], the present inner resistance R′ of the second battery 12 when it is assumed that the degradation diagnosis of the second battery 12 can be performed can be expressed by the following equation [2].

$${R}^{,} = R 0 \times ( 1 + α \times \sqrt{} ( T 0 + Δ T ) ) \qquad [ 2 ]$$

From this equation [2] and the above equation [1], it can be estimated that the resistance value increase rate (slope coefficient) ae from the time of the previous degradation diagnosis of the second battery 12 to the time of the current degradation diagnosis of the second battery 12 is the following equation [3].

$$α e = R 0 \times ( 1 + α \times \sqrt{} ( T 0 + Δ T ) ) / ( R 0 \times ( 1 + α \times \sqrt{} T 0 ) ) \qquad [ 3 ]$$

The estimated resistance value increasing rate de is multiplied by the internal resistance value R of the second battery 12, which is an actual measured value when the degradation diagnosis of the second battery 12 is performed last time, to estimate the present internal resistance value Re of the second battery 12 (Equation [4]).

$$Re = R \times ( 1 + α \times \sqrt{} ( T 0 + Δ T ) ) / ( 1 + α \times \sqrt{} T 0 ) \qquad [ 4 ]$$

When the diagnosis unit 74 estimates Re of the present inner resistance of the second battery 12, the process proceeds to S414.

### S414

The diagnosis unit 74 derives the power (=outgoing current× output voltage) that can be output from the second battery 12 based on the estimated present inner resistance Re of the second battery 12, and determines whether or not the derived power that can be output from the second battery 12 is equal to or greater than the third threshold value. The third threshold value is appropriately set based on the supply power required for the second battery 12 as the backup power supply of the first battery 11.

When the diagnosis unit 74 determines that the power that can be output from the second battery 12 is equal to or greater than the third threshold (S414, Yes), the process proceeds to S415. On the other hand, when the diagnosis unit 74 determines that the power that can be output from the second battery 12 is less than the third threshold (S414, No), the process proceeds to S416.

### S415

The diagnosis unit 74 determines that the state of the second battery 12 is normal because it is determined that the power that can be output from the second battery 12 is sufficient for backup. When it is determined that the state of the second battery 12 is normal, the present battery diagnosis process ends.

### S416

The diagnosis unit 74 determines that the state of the second battery 12 is abnormal because it is determined that the power that can be output from the second battery 12 is insufficient for backup. When it is determined that the state of the second battery 12 is abnormal, the present battery diagnosis process ends.

### Operations and Effects

As described above, according to the diagnosis method of the second battery 12 (redundant power supply) according to the embodiment of the present disclosure, when a highly accurate physical quantity capable of performing the deterioration diagnosis of the second battery 12 by the first diagnosis discharge process cannot be acquired, the diagnosis discharge process is repeatedly performed a plurality of times to acquire the physical quantity. This process increases the likelihood that a highly accurate physical quantity can be acquired, and thus increases the opportunity to perform the deterioration diagnosis of the second battery 12.

Further, according to the diagnosis method of the second battery 12 (redundant power supply) according to the present embodiment, when the second and third diagnostic discharge processes are performed, charging is performed until the amount of electricity stored in the second battery 12 reaches a predetermined high value. By this process, even if the second and third diagnostic discharge processes are continuously performed, it is possible to prevent the amount of electricity stored in the second battery 12 from excessively decreasing.

Further, according to the diagnosis method of the second battery 12 (redundant power supply) according to the present embodiment, a process of waiting for the start of the third diagnosis discharge process for a predetermined time from the end of the second diagnosis discharge process is performed. By this processing, it is possible to eliminate the influence of the polarization occurring in the second battery 12 on the physical quantity.

Further, according to the diagnosis method of the second battery 12 (redundant power supply) according to the present embodiment, when the deterioration diagnosis of the second battery 12 cannot be performed even after the first, second, and third diagnostic discharge processes, the internal resistance value of the current second battery 12 is estimated from the past information when the deterioration diagnosis of the second battery 12 can be performed. Then, the state of the second battery 12 is grasped based on the estimated internal resistance value. Through this process, it is possible to determine whether or not the second battery 12 can be used for automatic operation.

Although an embodiment of the present disclosure has been described above, the present disclosure can be regarded as a battery diagnosis device, a method for diagnosing a redundant power supply executed by a battery diagnosis device including a processor and a memory, a control program for executing a method for diagnosing a redundant power supply, a computer-readable non-transitory storage medium storing a control program, and a vehicle equipped with a battery diagnosis device.

The method for diagnosing a redundant power supply of the present disclosure can be used for diagnosing a state of a backup battery mounted in a vehicle.

What is claimed is:

1. A method of diagnosing a redundant power supply executed by a computer of a device that diagnoses a state of a battery mounted on a vehicle, the method comprising:
a step of performing a discharge process for discharging by a predetermined discharge pattern from the battery;
a step of performing a deterioration diagnosis of the battery when first information obtained by the discharge process satisfies a predetermined condition;
a step of estimating an internal resistance value of the battery based on second information acquired at the time of the latest diagnosis satisfying the predetermined condition, when the first information does not satisfy the predetermined condition; and
a step of determining the state of the battery using the estimated internal resistance value of the battery.

2. The method according to claim 1, wherein:
the first information is an average value of an outflow current of the battery in a discharge period; and
the predetermined condition is that the average value is not equal to or greater than a first threshold value.

3. The method according to claim 1, wherein:
the first information is an outflow current of the battery at a discharge end time point at which a discharge period has elapsed; and
the predetermined condition is that the outflow current is not equal to or greater than a second threshold value.

4. The method according to claim 1, wherein the second information includes the internal resistance value of the battery and an elapsed time from a start time when the battery is used to a present time.

5. The method according to claim 1, wherein the determination step derives, from the internal resistance value of the battery estimated in the estimation step, power that is able to be output from the battery, and determines that the battery is normal when the power that is able to be output is equal to or greater than a third threshold value.

6. A non-transitory storage medium storing a program executed by a computer of a device that diagnoses a state of a battery mounted on a vehicle, the program comprising:
a step of performing a discharge process for discharging by a predetermined discharge pattern from the battery;
a step of performing a deterioration diagnosis of the battery when first information obtained by the discharge process satisfies a predetermined condition;
a step of estimating an internal resistance value of the battery based on second information acquired at the time of the latest diagnosis satisfying the predetermined condition, when the first information does not satisfy the predetermined condition; and
a step of determining the state of the battery using the estimated internal resistance value of the battery.
